(19) United States
(12) Patent Application Publication
(10) Pub. No.: US 2005/0238808 A1
(43) Pub. Date: Oct. 27, 2005

(54) Methods for producing ruthenium film and ruthenium oxide film

(75) Inventors: Julien Gatineau, Ibaraki (JP); Christian Dussarrat, Ibaraki (JP)

Correspondence Address: Linda K. Russell, Suite 1800, 2700 Post Oak Blvd., Houston, TX, 77056, US

(73) Assignee: L'Air Liquide, Société Anonyme à Directoire et Conseil de Surveillance pour I'Etude et I'Exploita

(21) Appl. No.: 11/112,470

(22) Filed: Apr. 22, 2005

(30) Foreign Application Priority Data
Apr. 27, 2004 (JP) 2004-130756

(51) Int. Cl. C23C 16/00

(52) U.S. Cl. 427/248.1

(57) ABSTRACT

To provide a method that can relatively rapidly deposit a ruthenium film that adheres well to substrate and that also does not incorporate impurities.

Method for producing ruthenium film, characterized by reacting a gaseous volatile inorganic ruthenium compound with a gaseous reducing agent by introducing the gaseous volatile inorganic ruthenium compound and gaseous reducing agent into a reaction chamber (11) that holds at least one substrate and thereby depositing ruthenium on the at least one substrate.

Ruthenium and ruthenium oxide are the materials considered most promising for the capacitor electrode materials of next generation DRAMs. High dielectric constant materials such as alumina, tantalum pentoxide, hafnium oxide, and barium-strontium titanate are currently used for capacitor electrodes. These materials, however, are produced using temperatures as high as 600° C., which results in oxidation of polysilicon, silicon, or aluminum and causes a loss of capacitance. Both ruthenium and ruthenium oxide, on the other hand, exhibit a high oxidation resistance and high conductivity and are suitable for application as capacitor electrode materials. They also function effectively as oxygen diffusion barriers. Ruthenium has also been proposed for the gate metal for lanthanide oxides. In addition, ruthenium is more easily etched by ozone and by a plasma using oxygen than is platinum and other noble metal compounds. The use of ruthenium as a barrier layer separating low-k material from plated copper and as a seed layer has also recently been attracting attention.

Numerous precursors have been investigated for ruthenium deposition by chemical vapor deposition (CVD) and more recently by atomic layer deposition (ALD). While approximately 30 different precursors have been employed to date as precursors for ruthenium or ruthenium oxide deposition, three main precursors are currently in use. The most frequently used precursor is bis(ethylcyclopentadienyl)ruthenium or Ru(EtCp)₂ (see Nonpatent Reference 1 and Patent Reference 1). This precursor is either used as such or after dissolution in a solvent such as tetrahydrofuran. It is a liquid at room temperature and has a vapor pressure of 0.1 torr at 75° C. Ruthenium film is produced from this precursor by CVD at temperatures of 300-400° C. (see Nonpatent Reference 1), while ruthenium oxide film is produced by ALD using oxygen as an additional reactant (see Patent Reference 1). A second precursor is ruthenocene (RuCp₂), which has a melting point of about 200° C. and is processed with the same reactants and in the same temperature range as for Ru(EtCp)₂ (see Nonpatent Reference 2 and Nonpatent Reference 3). CVD using this precursor is described in Nonpatent Reference 3, while its ALD process is described in Nonpatent Reference 4. A third precursor, tris(2,4-octanedionate)ruthenium (Ru(OD)₃), is a liquid at room temperature and has a vapor pressure of 1 torr at 200° C. A contemporary process for forming ruthenium film using this precursor is the CVD method at about 300° C. that is described in Nonpatent Reference 4.

[Patent Reference 1]

U.S. Pat. No. 6,580,111
   [Nonpatent Reference 1]
S. Y. Kang et al., J. Korean Phys. Soc., 2000, Vol. 37, No. 6, 1040-1044
   [Nonpatent Reference 2]
S-E. Park et al., J. Electrochemical Soc., 2000, 147, 203-209
   [Nonpatent Reference 3]
T. Aaltonen et al., Electrochemical Society Proceedings, 2003-08
   [Nonpatent Reference 4]
J-H. Lee et al., Electrochemical and Solid-State Letters, 1999, 2, 622-623

However, it has been reported that the ruthenium-type films afforded by vapor deposition using the aforementioned prior-art precursors are poorly adhesive for organic base layers and for glass, silicon, silicon oxide, and tantalum pentoxide film. It has also been reported that these ruthenium-type films are poorly adhesive for nitride films and oxide films. Nonpatent Reference 3 does report good adhesiveness to an underlying alumina film, but when an alumina film—which is a high-k material—is not present, ruthenium-type films assume a heterogeneous state in which micropores are present.

A number of patents and articles have also reported the presence of impurities in ruthenium-type films. The presence of carbon in the grown film is the biggest problem because carbon increases the resistance of ruthenium-type films. The presence of oxygen, hydrogen, and fluorine impurities originating from the composition of the prior-art precursors has also been reported. Another problem is the incubation time of Ru(EtCp)₂. In order to avoid this incubation time in the initial stage of growth, it has been reported that a seed layer must be applied by sputtering prior to ruthenium deposition using Ru(EtCp)₂. In addition, some of the prior-art precursors have very low volatilities, which results in slow ruthenium-type film deposition with these precursors.

The object of the present invention therefore is to provide a method that solves the aforementioned problems with the prior art and more particularly that can relatively rapidly deposit a ruthenium or ruthenium oxide film that adheres well to substrate and that also does not incorporate impurities.

According to a first aspect of the present invention, there is provided a method for producing ruthenium film that is characterized by reacting a gaseous volatile inorganic ruthenium compound with a gaseous reducing agent by introducing the gaseous volatile inorganic ruthenium compound and gaseous reducing agent into a reaction chamber that holds at least one substrate and thereby depositing ruthenium on the at least one substrate.

According to a second aspect of the present invention, there is provided a method for the production of ruthenium oxide film that is characterized by
introducing gaseous volatile ruthenium oxide into a reaction chamber that holds at least one substrate and
decomposing the volatile ruthenium oxide under the application of heat and depositing a ruthenium oxide film on the at least one substrate.

The present invention enables the relatively rapid deposition of a ruthenium or ruthenium oxide film that adheres well to substrate and that also does not incorporate impurities.

The present invention is explained in greater detail hereinbelow.

A volatile inorganic ruthenium compound is used in this invention as the ruthenium precursor for ruthenium film production. Specific examples of this inorganic ruthenium compound are volatile inorganic ruthenium oxides such as ruthenium trioxide (RuO₃) and ruthenium tetroxide (RuO₄) and volatile inorganic ruthenium halides such as ruthenium pentafluoride (RuF₅), ruthenium hexafluoride (RuF₆), and ruthenium trichloride (RuCl₃); however, the volatile inorganic ruthenium compound is not limited to these specific examples. The present invention can use a single such inorganic ruthenium compound or a mixture of two or more. Ruthenium tetroxide is particularly preferred for the inorganic ruthenium compound.

Ruthenium film deposition in accordance with the present invention comprises introduction of the volatile inorganic ruthenium compound in the vapor phase into a reaction chamber that holds at least one substrate and introduction of gaseous reducing agent into this reaction chamber.

The reducing agent reduces the inorganic ruthenium compound according to the present invention and thereby converts it into ruthenium metal. This reducing agent can be specifically exemplified by hydrogen (H₂), trisilylamine (N(SiH₃)₃), silane (SiH₄), disilane (Si₂H₆), trisilane (Si₃H₈), diborane (B₂H₆), and hexachlorodisilane (Si₂Cl₆), but is not limited to these specific examples. The present invention can use a single such reducing agent or a mixture of two or more. Hydrogen is particularly preferred for the reducing agent.

Chemical vapor deposition (CVD) and atomic layer deposition (ALD) can be used by the present invention to form the ruthenium film.

CVD employs the coexistence in the reaction chamber of the vapor-phase inorganic ruthenium compound with the vapor-phase reducing agent. In this case the inorganic ruthenium compound and reducing agent react in the gas phase: the inorganic ruthenium compound is reduced to ruthenium, which deposits on the substrate. The total pressure in the reaction chamber is preferably maintained at 0.01-1000 torr and more preferably 0.1-10 torr, while the substrate is heated preferably to 50-800° C. and more preferably to 100-400° C. The quantity of reducing agent admitted into the reaction chamber should be sufficient for reduction of the inorganic ruthenium compound by the reducing agent into ruthenium metal. When, for example, ruthenium tetroxide is used as the inorganic ruthenium compound and hydrogen is used as the reducing agent, at least 1 mole hydrogen is used per mole ruthenium tetroxide. The reaction by-product in this case is H₂O.

Considered in terms of the reactive compounds involved (the inorganic ruthenium compound and/or reducing agent), in ALD only the inorganic ruthenium compound is first introduced into the reaction chamber and a very thin layer (monoatomic layer) of the inorganic ruthenium compound is formed on the substrate by adsorption. The interior of the reaction chamber is then purged with an inert gas (nitrogen, helium, etc.) in order to remove unreacted (unadsorbed) inorganic ruthenium compound, after which only reducing agent is admitted into the reaction chamber. The introduced reducing agent reacts with the monoatomic layer of inorganic ruthenium compound present on the substrate, thereby reducing the inorganic ruthenium compound to ruthenium metal. This results in the formation of a monoatomic layer of ruthenium on the substrate. When the formation of a thicker ruthenium film is desired, the unreacted reducing agent and the vapor-phase reaction product from the inorganic ruthenium compound and reducing agent are purged from the reaction chamber and the following sequence can then be repeated: introduction of the inorganic ruthenium compound, removal of the residual ruthenium compound by purging, introduction of the reducing agent, and removal of the reducing agent and vapor-phase reaction product by purging.

A pulse regime can be used in the ALD process to carry out introduction of the inorganic ruthenium compound and reducing agent. For example, the inorganic ruthenium compound can be introduced for 0.01-10 seconds at a flow rate of 0.1-10 sccm, while the reducing agent can be introduced, for example, for 0.01 second at a flow rate of 0.5-100 sccm. The purge gas can be introduced, for example, for 0.01-10 seconds at a flow rate of 100-200 sccm.

The total pressure in the reaction chamber in the ALD process is preferably maintained at 0.1-10 torr, while the substrate temperature is preferably maintained at 100-600° C.

A volatile ruthenium oxide is used in this invention as the ruthenium oxide precursor for production of ruthenium oxide film. This volatile ruthenium oxide can be exemplified as above. Ruthenium tetroxide is preferably used for the volatile ruthenium oxide.

In order to form a (solid) ruthenium oxide film using the present invention, volatile ruthenium oxide is introduced into a reaction chamber that holds at least one substrate. The substrate is heated at this point to a temperature at which the volatile ruthenium oxide undergoes decomposition with the production of solid ruthenium oxide (ruthenium dioxide), and the solid ruthenium oxide afforded by this decomposition of the volatile ruthenium oxide deposits on the substrate. The solid inorganic ruthenium compound functions as a decomposition catalyst for the volatile ruthenium oxide. Accordingly, once the volatile ruthenium oxide has undergone thermal decomposition and the thereby produced solid ruthenium oxide has deposited on the substrate, thorough decomposition of the volatile ruthenium oxide can still be achieved even when the heating temperature is reduced. The use of ruthenium tetroxide as the volatile ruthenium oxide is particularly preferred. The total pressure in the reaction chamber during this ruthenium oxide deposition is preferably established at 0.01-10 torr and more preferably is established at 0.1-5 torr. The substrate is preferably heated to at least 250° C. and more preferably is heated to 350-400° C.

The volatile inorganic ruthenium compound (ruthenium precursor) and reducing agent can be introduced into the reaction chamber in this invention diluted with inert gas. This inert gas can be, for example, nitrogen, argon, helium, and so forth.

The volatile inorganic ruthenium compound can be introduced into the reaction chamber in this invention using a bubbler technique. More specifically, the volatile inorganic ruthenium compound can be stored in a container that is maintained by a bath at preferably −50° C. to 100° C. and more preferably −10° C. to 50° C.; an inert gas can be bubbled into the volatile inorganic ruthenium compound using an inert gas bubbling tube; and the volatile inorganic ruthenium compound entrained in the inert gas can then be introduced into the reaction chamber. The volatile inorganic ruthenium compound may also be stored in the container as a solution in solvent.

The substrate for the present invention can be exemplified by semiconductor substrates such as silicon substrates. The following, for example, may have been formed on this semiconductor substrate: low-k film, high-k film, C-doped silicon dioxide film, titanium nitride film, copper film, tantalum nitride film, molybdenum film, tungsten film, and ferroelectric film. The ruthenium film and ruthenium oxide film produced in accordance with the present invention both exhibit an excellent adhesiveness for these films and do not separate or debond even when subjected to chemical mechanical polishing (CMP). In addition, the incorporation of impurities such as carbon, hydrogen, and halogen (e.g., fluorine) into these ruthenium and ruthenium oxide films is entirely absent. The requirement for incubation is also eliminated by the present invention, which enables deposition (growth) of the ruthenium or ruthenium oxide film in shorter periods of time.

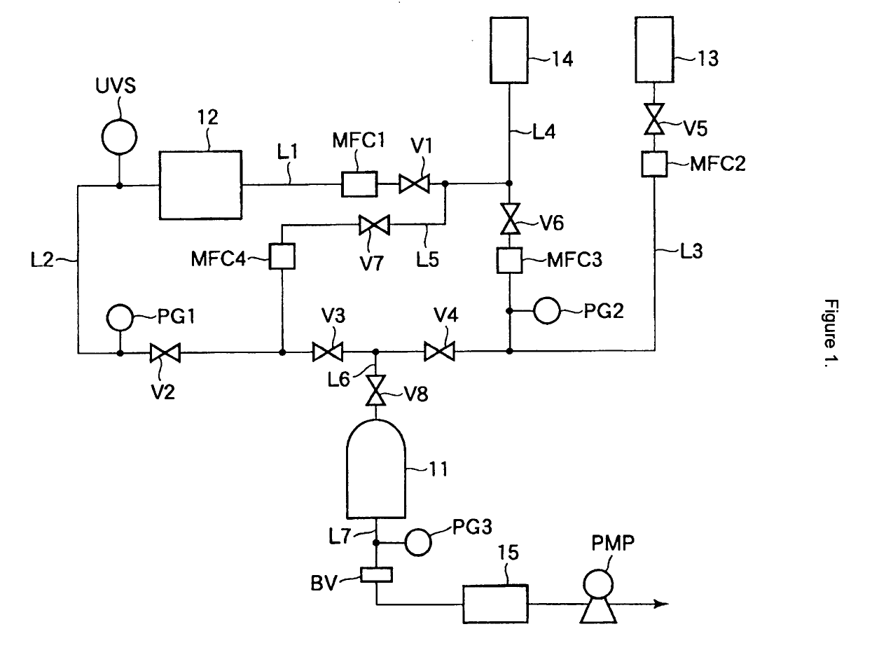

FIG. 1 contains a block diagram that schematically illustrates an example of a CVD-based apparatus that can be used to execute the inventive method for producing ruthenium or solid ruthenium oxide film.

The apparatus illustrated in FIG. 1 is provided with a reaction chamber 11, a feed source 12 for a volatile inorganic ruthenium compound, a feed source 13 for reducing agent gas, and a feed source 14 for an inert gas typically used as a carrier gas and/or dilution gas. In the case of a single-wafer tool, a susceptor (not shown in the figure) is provided in the reaction chamber 11 and a single semiconductor substrate (not shown in the figure), for example, a silicon substrate, is mounted on this susceptor. A heater is provided within the susceptor in order to heat the semiconductor substrate to the desired reaction temperature. In the case of a batch tool, from 5 to 200 semiconductor substrates are held within the reaction chamber 11. The heater in a batch tool may have a different structure from the heater in a single-wafer tool.

The volatile inorganic ruthenium compound feed source 12 uses a bubbler method as described above to introduce a volatile inorganic ruthenium compound into the reaction chamber 11, and is connected to the inert gas feed source 14 by the line L1. The line L1 is provided with a shutoff valve V1 and a flow rate controller, for example, a mass flow controller MFC1, downstream from this valve. The volatile ruthenium compound is introduced from its feed source 12 through the line L2 into the reaction chamber 11. The following are provided considered from the upstream side: an ultraviolet spectrometer UVS, a pressure gauge PG1, a shutoff valve V2, and a shutoff valve V3. The ultraviolet spectrometer UVS functions to confirm the presence of the volatile inorganic ruthenium compound in the line L2 and to detect its concentration.

The reducing agent gas feed source 13 comprises a vessel that holds the reducing agent in gaseous form. The reducing agent gas is introduced from its feed source 13 through the line L3 into the reaction chamber 11. A shutoff valve V4 is provided in the line L3. This line L3 is connected to the line L2.

The inert gas feed source 14 comprises a vessel that holds inert gas in gaseous form. The inert gas can be introduced from its feed source through the line L4 into the reaction chamber 11. Line L4 is provided with the following considered from the upstream side: a shutoff valve V6, a mass flow controller MFC3, and a pressure gauge PG2. The line L4 joins with the line L3 upstream from the shutoff valve V4.

The line L5 branches off upstream from the shutoff valve V1 in the line L1; this line L5 joins the line L2 between the shutoff valve V2 and the shutoff valve V3. The line L5 is provided with a shutoff valve V7 and a mass flow controller MFC4 considered from the upstream side.

The line L6 branches off between the shutoff valves V3 and V4 into the reaction chamber 11. This line L6 is provided with a shutoff valve V8.

A line L7 that reaches to the pump PMP is provided at the bottom of the reaction chamber 11. This line L7 contains the following considered from the upstream side: a pressure gauge PG3, a butterfly valve BV for controlling the backpressure, and a hot trap 15. This hot trap 15 comprises a tube that is provided with a heater over its circumference. Since the volatile inorganic ruthenium compound is converted into a solid ruthenium compound by thermal decomposition, the volatile inorganic ruthenium compound introduced into the hot trap 15 is converted into a solid ruthenium compound and deposits on the inner wall of the tube and in this manner can be removed from the gas stream.

The production of ruthenium film using the apparatus illustrated in FIG. 1 commences with the closing of shutoff valves V1, V2, and V5 and the opening of shutoff valves V6, V7, V3, V4, and V8 and the introduction of inert gas by the action of the pump PMP from the inert gas feed source 14 through the line L4 into the line L6 and into the reaction chamber 11.

The shutoff valve V5 is then opened and reducing agent gas is introduced into the reaction chamber 11 from the reducing agent gas feed source 13. The shutoff valves V1 and V2 are opened and inert gas is introduced from the inert gas feed source 14 through the line L1 and into the volatile inorganic ruthenium compound feed source 12. This results in the introduction of gaseous inorganic ruthenium compound through the line L2 and the line L6 into the reaction chamber 11. The reducing agent gas and volatile inorganic ruthenium compound react in the reaction chamber 11, resulting in deposition of ruthenium metal on the semiconductor substrate.

In order to produce a solid ruthenium oxide film using the apparatus illustrated in FIG. 1, the apparatus is prepped by closing the shutoff valve V5 (and maintaining it closed) since the reducing agent will not be used and also by closing the shutoff valves V4, V6, and V7 (and maintaining them closed). While the apparatus is in this state, the shutoff valves V1, V2, V3, and V8 are opened and inert gas is introduced under the action of the pump PMP from the inert gas feed source 14 through the line L4 and the line L1 into the volatile ruthenium oxide feed source 12. Gaseous volatile ruthenium oxide is then introduced into the reaction chamber 11 through the line L2 and the line L6. The reaction chamber 11 is heated and the volatile ruthenium oxide introduced into the reaction chamber 11 is thereby thermally decomposed and converted into solid ruthenium oxide, which deposits on the substrate.

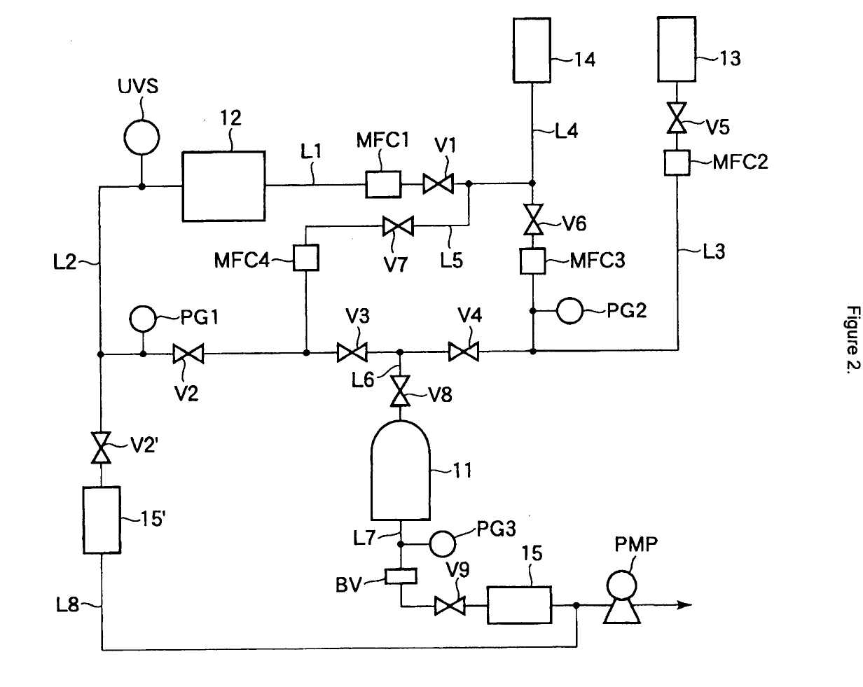

FIG. 2 contains a block drawing that schematically illustrates an example of an ALD-based apparatus that can be used to execute the inventive method for producing ruthenium film.

The apparatus illustrated in FIG. 2 comprises the apparatus illustrated in FIG. 1 that is provided with a line L8 that itself is provided with a shutoff valve V2′ and, downstream from the shutoff valve V2′, with a hot trap 15′ that is identical to the hot trap 15. Otherwise, those elements that are the same as in FIG. 1 have been assigned the same reference symbol and will not be described in detail again. One end of the line L8 is connected to the line L2 between the ultraviolet spectrometer UVS and the pressure gauge PG1 and the other end is connected to the line L7 between the hot trap 15 and the pump PMP.

The production of ruthenium film by ALD using the apparatus illustrated in FIG. 2 commences with the closure of the shutoff valves V2 and V5 and opening of the shutoff valves V6, V7, V3, V4, V8, and V9 and also the shutoff valves V1 and V2′. Through the action of the pump PMP, inert gas is introduced from the inert gas feed source 14 through the line L4 and the line L6 into the reaction chamber 11 and the volatile ruthenium compound is transported along with the inert gas in the lines L1, L2, and L8.

Once the initial set up is completed, the shutoff valve V2′ is closed and the shutoff valve V2 is opened and a pulse of the volatile ruthenium compound is introduced into the reaction chamber 11. This is followed by closure of the shutoff valve V2, opening of the shutoff valve V2′, and closure of V2, thereby passing the volatile ruthenium compound along with inert gas into the line L8 and discharging same from the system, while also introducing inert gas into the reaction chamber 11 and purging the interior of the reaction chamber, thereby removing unreacted inorganic ruthenium compound from within the reaction chamber 11. This is followed by the opening of shutoff valve V5, which results in the introduction into the reaction chamber 11 of a pulse of reducing gas from the reducing agent gas feed source 13 along with inert gas from the inert gas feed source 14. The shutoff valve V5 is then closed, resulting in the introduction of a pulse of inert gas into the reaction chamber 11 that removes reaction by-products, unreacted reducing agent, etc., from the reaction chamber 11. This process cycle can be repeated until a ruthenium film with the desired thickness is obtained.

FIG. 1 contains a block drawing that schematically illustrates an example of an apparatus for executing the method according to the present invention.

FIG. 2 contains a block drawing that schematically illustrates another example of an apparatus for executing the method according to the present invention.

### EXAMPLES

The invention is described below through examples, but is not limited by these examples.

### Example 1

A silicon semiconductor bearing a silicon dioxide film on its surface and a silicon substrate were mounted in a reaction chamber. Nitrogen was bubbled into a vessel containing liquid ruthenium tetroxide and the resulting stream of ruthenium tetroxide-bearing nitrogen was introduced into the reaction chamber concurrently with the introduction of hydrogen at a concentration of 0.5 volume % with respect to nitrogen. A total pressure of 3 torr was established in the reaction chamber and the substrate temperature was set at 250° C. This procedure resulted in the deposition of a ruthenium metal film on the substrates; the ruthenium metal deposition rate in this case was about 100 Å/minute. The resulting ruthenium oxide film was tightly bonded to the silicon substrate and to the silicon dioxide film on the silicon substrate. In addition, the bonding strength by the ruthenium metal for the silicon substrate and silicon dioxide film was increased by the use of higher substrate temperatures.

### Example 2

A ruthenium metal film was formed on the following films using the same procedure as in Example 1 (with the exception that a substrate temperature of 200° C. was used): alumina film, low-k film, hafnium oxide (HfO₂) film, lanthanum oxide (La₂O₃) film, tantalum nitride (TaN) film, tantalum oxide (Ta₂O₅) film, titanium nitride (TiN), BST film, and PZT film. The ruthenium metal deposition rate did not depend on the nature of the film and was about 70 Å/minute in each case. Moreover, the ruthenium metal was tightly bonded to each film.

### Example 3

A silicon semiconductor bearing a silicon dioxide film on its surface and a silicon substrate were mounted in a reaction chamber. A thin layer of ruthenium oxide was formed on each substrate by bubbling nitrogen at a flow rate of 10 sccm into a vessel holding liquid ruthenium tetroxide and introducing the resulting dilute ruthenium tetroxide (ruthenium tetroxide-bearing nitrogen) for 0.5 second at a flow rate of 0.1 sccm into the reaction chamber. The unreacted ruthenium tetroxide was then removed by purging the interior of the reaction chamber with nitrogen. Hydrogen was subsequently introduced into the reaction chamber for 1 second at a flow rate of 1.2 sccm along with nitrogen as diluent. The total flow rate of the nitrogen used as diluent was 174 sccm. The pressure within the reaction chamber was maintained at 4 torr. The substrate temperature was set at 150° C.

The interior of the reaction chamber was then purged with nitrogen, after which the above-described cycle was repeated to obtain a ruthenium metal film of the desired thickness. The ruthenium metal deposition rate was approximately 2.5 Å per cycle.

### Example 4

A ruthenium metal film was formed on the following films using the same procedure as in Example 3 (with the exception that a substrate temperature of 200° C. was used): alumina film, low-k film, hafnium oxide (HfO₂) film, lanthanum oxide (La₂O₃) film, tantalum nitride (TaN) film, tantalum oxide (Ta₂O₅) film, titanium nitride (TiN), BST film, and PZT film. The ruthenium metal deposition rate did not depend on the nature of the film and was about 2.5 Å per cycle in each case. Moreover, the ruthenium metal was tightly bonded to each film.

### Example 5

A silicon semiconductor bearing a silicon dioxide film on its surface and a silicon substrate were mounted in a reaction chamber. Nitrogen was bubbled at a flow rate of 27 sccm into a vessel holding liquid ruthenium tetroxide and the ruthenium tetroxide-bearing nitrogen was introduced into the reaction chamber. A total pressure of 1 torr was established in the reaction chamber and the substrate temperature was set at 400° C. An extremely uniform ruthenium oxide film with a thickness of about 400 Å was obtained on each film in 3 minutes (deposition rate about 133 Å/minute) under these conditions. The obtained ruthenium oxide film was tightly bonded to the silicon substrate and to the silicon dioxide film on the silicon substrate.

### REFERENCE SYMBOLS

11 reaction chamber
12 volatile inorganic ruthenium compound feed source
13 reducing agent gas feed source
14 inert gas feed source

1-12. (canceled)

13. A method for producing ruthenium film, characterized by reacting a gaseous volatile inorganic ruthenium compound with a gaseous reducing agent by introducing the gaseous volatile inorganic ruthenium compound and gaseous reducing agent into a reaction chamber that holds at least one substrate and thereby depositing ruthenium on the at least one substrate.

14. The production method of claim 13, wherein the volatile inorganic ruthenium compound is at least one ruthenium compound selected from the group consisting of:
a) ruthenium trioxide;
b) ruthenium tetroxide;
c) ruthenium pentafluoride;
d) ruthenium hexafluoride; and
e) ruthenium trichloride.

15. The production method of claim 13, wherein the reducing agent contains hydrogen, trisilylamine, silane, disilane, trisilane, diborane, hexachlorodisilane, or a mixture of two or more of the preceding.

16. The production method of claim 13, wherein the pressure in the reaction chamber is maintained at 0.01-1000 torr.

17. The production method of claim 13, wherein deposition is carried out at a substrate temperature of 50-800° C.

18. The production method of claim 13, wherein the volatile inorganic ruthenium compound and reducing agent coexist within the reaction chamber.

19. The production method of claim 13, characterized by:
a) first introducing the volatile inorganic ruthenium compound, insofar as the volatile inorganic ruthenium compound and reducing agent are concerned, into the reaction chamber and thereby forming a layer of the volatile inorganic ruthenium compound on the substrate;
b) purging the interior of the reaction chamber; and
c) introducing the reducing agent into the reaction chamber and reducing the volatile inorganic ruthenium compound.

20. The production method of claim 19, characterized by:
a) purging the interior of the reaction chamber after the reduction; and
b) thereafter carrying out introduction of the volatile inorganic ruthenium compound and introduction of the reducing agent repetitively wherein the interior of the reaction chamber is purged between introduction of the volatile inorganic ruthenium compound and introduction of the reducing agent.

21. The production method of claim 19, wherein deposition is carried out at a substrate temperature of 100-600° C.

22. A method for the production of ruthenium oxide film, characterized by:
a) introducing gaseous volatile ruthenium oxide into a reaction chamber that holds at least one substrate; and
b) decomposing the volatile ruthenium oxide under the application of heat and depositing a ruthenium oxide film on the at least one substrate.

23. The production method of claim 22, wherein the total pressure within the reaction chamber is established at 0.01-10 torr.

24. The production method of claim 22, wherein the aforesaid decomposition is carried out at a substrate temperature of at least 250° C.
